(19) United States
(12) Patent Application Publication
(10) Pub. No.: US 2011/0088747 A1
(43) Pub. Date: Apr. 21, 2011

(54) PHOTOVOLTAIC DEVICE

(75) Inventors: Jan Alstrup, Thisted (DK); Ole Hagemann, Roskilde (DK); Mikkel Jørgensen, Glostrup (DK); Torben Damgaard Nielsen, Copenhagen Ø (DK); Frederik Christian Krebs, Lyngby (DK)

(73) Assignee: THE TECHNICAL UNIVERSITY OF DENMARK

(21) Appl. No.: 12/988,784

(22) PCT Filed: Apr. 16, 2009
(86) PCT No.: PCT/EP09/54559

§ 371 Date: Dec. 13, 2010

(30) Foreign Application Priority Data
Apr. 21, 2008 (GB) 0807211.8

(51) Int. Cl. H01L 31/05; H01L 31/18; A42B 1/24

(52) U.S. Cl. 136/244; 438/80; 2/209.13; 257/E31.124

(57) ABSTRACT

A photovoltaic cell module including a plurality of serially connected photovoltaic cells on a common substrate, each including a first electrode, a printed light-harvesting layer and a printed second electrode, wherein at least one of the electrodes is transparent, and wherein the second electrode of a first cell is printed such that it forms an electrical contact with the first electrode of an adjacent second cell without forming an electrical contact with the first electrode of the first cell or the light-harvesting layer of the second cell, and a method of making such photovoltaic cell modules.

The present invention relates to serially-connected photovoltaic devices, a method of forming serially-connected photovoltaic devices, and to an assembly including such devices. Photovoltaic devices inter-convert light and electricity.

Solar power is an important renewable energy source, and can be harvested using photovoltaic cells (solar cells). Renewable energy sources are desirable for a number of reasons. First, such energy sources enable a reduction in consumption of non-renewable energy sources. Second, such energy sources enable the use of electrical devices without the need for a mains power source. This is of particular interest in remote locations, for example at sea or in developing countries.

In solar cells, photons are absorbed and the energy of the photon forms an exciton consisting of an electron and a hole which initially are bound together. These can be separated into free charge carriers and caused to migrate towards respective electrodes by an electric field, suitably produced by electrodes of differing work functions. Cells containing two components (heterojunction cells) can give much higher efficiency than cells containing a single component because of increased charge separation at the interface between the two components.

In electroluminescent devices, which can also be photovoltaic devices, electrons and holes injected at opposed electrodes reach one another by conduction and recombine to produce light.

Solar cells may rely on photovoltaic polymers. It has been recognised that potentially such devices have advantages over the conventional, similar devices based on inorganic semiconductors. These potential advantages include cheapness of the materials and versatility of processing methods, flexibility (lack of rigidity) and toughness. In particular, there is the potential advantage of high volume production at low unit cost.

Photovoltaic polymers can be derived from chemically doped conjugated polymers, for example partially oxidised (p-doped) polypyrrole. The article ‘Conjugated polymers: New materials for photovoltaics’, Wallace et al, Chemical Innovation, April 2000, Vol. 30, No. 1, 14-22 reviews the field.

Fréchet et al. (WO2005/107047) have disclosed polymer solar cells containing a layer of metal oxide and a layer of thermocleavable polythiophene.

Risø National Laboratory (GB2424512) has disclosed the use of a thermocleavable polythiophene layer and a fullerene layer in polymer solar cells.

In order to reduce the production cost of polymer solar cells, it is necessary to exclude production steps that increase the production time or cost, such as steps that must be carried out under vacuum or inert atmosphere. Ideally, the use of protective layers not contributing directly to the functioning of the device would be reduced or excluded. In particular, the encapsulation of the device to exclude oxygen should be avoided.

It is currently usual, when forming polymer solar cells, to use two vacuum steps: one to form the transparent front electrode, usually of indium tin oxide (ITO), and one to form the metallic back electrode by vapour deposition. These steps are slow and thus expensive. This somewhat negates the inherent advantage of polymer solar cells of being able to produce the required polymer layers using solution techniques. Thus, it is an aim to produce solar cells with fewer vacuum processing steps.

In addition, ITO is an expensive component in itself: indium currently costs around 1000$ per kg. Also, the available reserves in the earth's crust are estimated to be rather low and certainly not sufficient for large scale production of solar cells. Thus, it is an aim to avoid the use of indium-containing compounds in polymer solar cells.

In addition, the use of other expensive materials should be avoided where possible. The most efficient polymer solar cells known to date rely on fullerene derivatives as electron acceptors and electron conductors. While these materials are now available on a large scale, these are still expensive and make a significant contribution to the overall cost of the cell. It is therefore an aim to provide efficient solar cells without the need for fullerene derivatives.

The use of steps requiring very high temperatures, the use of clean rooms or glove box conditions, and complex processing steps should also be avoided where possible in order to increase the cost efficiency of polymer solar cells.

The use of serial connections between photovoltaic devices increases the total voltage output of a module comprising several devices compared with that of a single device. Gaudiana (US2005/0263179) describes methods of forming serial connections between solar cells by providing a conductive stitch, mesh, paste or other form of interconnect between separate cells. Evans (U.S. Pat. No. 4,341,918) describes a method of forming serially connected doped silicon solar cells.

It is an aim of the present invention to provide a photovoltaic module of serially connected photovoltaic devices having a simple construction which may be adapted to any desired shape.

In a first aspect, the present invention provides a photovoltaic cell module comprising a plurality of serially connected photovoltaic cells on a common substrate, each comprising a first electrode, a printed light-harvesting layer and a printed second electrode, wherein at least one of the electrodes is transparent, and wherein the second electrode of a first cell is printed such that it forms an electrical contact with the first electrode of an adjacent second cell without forming an electrical contact with the first electrode of the first cell or the light-harvesting layer of the second cell.

Preferably, the first electrode is transparent. Preferably, the substrate is transparent. Where only the first electrode is transparent, it is necessary that the substrate is also substantially transparent, to allow light to reach the layers of hole conducting polymer and electron conducting material. This gives high cell efficiency. Suitable substrates include glass, plastics and cloth.

A suitable transparent electrode is indium tin oxide (ITO). However, as discussed above, the use of a transparent electrode other than ITO is preferred. Preferred transparent electrode layers may be formed from fluorine tin oxide (FTO), a high conductivity organic polymer such as PEDOT:PSS or a metal grid—high conductivity organic polymer composite, or from materials such as gold, silver, aluminium, calcium, platinum, graphite, gold-aluminium bilayer, silver-aluminium bilayer, platinum-aluminium bilayer, graphite-aluminium bilayer, and calcium-silver bilayer, tin oxide-antimony, using methods known in the art, such as application of a solution of a salt of the required electrode material. For example, Pode et al. (Applied Physics Letters, 2004, 84, 4614-4616) describes a method of forming a transparent calcium-silver bilayer electrode; Hatton et al. (Journal of Materials Chemistry, 2003, 13, 722-726) describes a method of producing a transparent gold electrode; Neudeck and Kress (Journal of Electroanalytical Chemistry, 1997, 437, 141-156) describe the formation of laminated gold micro-meshes for use as transparent electrodes. The transparent electrode layer may be formed by application of a solution of a salt of the selected metal. For example, a platinum electrode layer is formed by application of a freshly-made solution (5×10⁻³ M) of H₂PtCl₆ in isopropanol using an air-brush.

A preferred transparent electrode layer may be formed as a silver grid under a PEDOT:PSS layer, as described by Aernouts et al. (Thin Solid Films 22 (2004) pp 451-452). Alternatively, an aluminium grid with a PEDOT:PSS overlayer or a screen printed silver grid with a screen printed PEDOT:PSS overlayer may be used (see below). Such methods of producing the transparent electrode layer may avoid the use of vacuum processing steps, in accordance with one of the aims of the invention.

Preferably, the photovoltaic cells are formed as nested loops, such as concentrically-arranged loops. Suitably, the loops may be open or closed loops, for example a horseshoe shape, triangular loop, square loop, pentagonal loop etc. This permits a cell module to be formed in a wide range of desired shapes while only requiring two terminals. The advantage of such a design is that the device can be made to match the surface available while maximizing the power output. For instance, if a circular area is available a module design with serially connected cells comprising stripes or linearly shaped cells does not geometrically match the surface available.

It may in some circumstances be preferred to form the photovoltaic cells as nested open loops, for example where it is desired to print a conductor extending from the centre of the module to an outer edge of the module. In other circumstances, closed loops may be preferred.

Preferably, the photovoltaic cells each have a substantially identical light-harvesting area. At the connection between each cell in the module, it is necessary for the electrons from one cell to recombine with holes from the adjacent cell. When the light-harvesting areas of each cell are substantially identical, each electron will be provided with a hole with which to combine, and so the use of the incident photons is efficient. In contrast, where one cell has a larger light-harvesting area, the extra charge carriers produced by photons incident on that cell will not be able to recombine due to lack of opposite charge carriers produced by adjacent cells, and so those extra charge carriers will not be able to contribute to the output of the module.

Preferably, in each cell of the module between at least one of the electrodes and the light-harvesting layer is provided a charge transport layer. Suitably, an electron transport layer and/or a hole transport layer may be provided. The arrangement of the charge transport layer(s) in the cells may determine the polarity of the electrodes of the cells, and hence of the terminals of the module. Preferably, an electron transport layer comprises metal oxide nanoparticles. Preferably, the metal oxide is selected from the group consisting of: TiO₂, TiOₓ and ZnO. Preferably, a hole transport layer comprises a hole conducting polymer, such as PEDOT:PSS, PEDOT:PTS, vapour phase deposited PEDOT, polyprodot, polyaniline, or polypyrrole. PEDOT:PSS is preferred.

Preferably, in each cell of the module, between one electrode and the light harvesting layer is provided an electron transport layer, and between the other electrode and the light harvesting layer is provided a hole transport layer. Suitably, the electrode adjacent to the electron transport layer is the first electrode.

Suitably, the light harvesting layer may comprise a thermocleavable polythiophene layer and a fullerene layer as described in GB2424512, or may be any other suitable light harvesting layer known in the art.

Preferably, the light harvesting layer comprises a bulk heterojunction layer comprising metal oxide nanoparticles and a hole conducting polymer which has been thermally treated to decrease its solubility, wherein the metal oxide is selected from the group consisting of: TiO₂, TiOₓ, ZnO, CeO₂ and Nb₂O₅. The metal oxide in the bulk heterojunction layer is preferably ZnO.

In certain cases it may be preferred to combine one metal oxide in the electron transport layer with a different metal oxide in the bulk heterojunction layer. This choice may be made with reference to the relative position of the electronic energy levels of the different metal oxides.

Suitable hole conducting polymers for the bulk heterojunction layer include poly(terphenylene-vinylene), polyaniline, polythiophene, poly(2-vinyl-pyridine), poly(N-vinylcarbazole), poly-acetylene, poly(p-phenylenevinylene) (PPV), poly-o-phenylene, poly-m-phenylene, poly-p-phenylene, poly-2,6-pyridine, poly(3-alkyl-thiophene) or polypyrrole substituted with thermally cleavable groups. Polythiophene derivatives substituted with thermally cleavable groups are particularly preferred. For example, polythiophenes and copolymers of thiophene with aryl monomers, such as benzothiadizole, thienopyrazine, fluorene or dialkylfluorenes, or dithienocyclopentadiene, which copolymers bear thermocleavable sidegroups, are preferred.

Preferably, the thermally cleavable groups improve the solubility of the hole conducting polymer in one or more solvents. This permits the use of solution-based methods for formation of the bulk heterojunction layer.

Preferably, after thermal cleavage the hole conducting polymer contains groups capable of strong, non-covalent interactions (most preferably free carboxylic acid groups) so that the polymer forms a hard insoluble matrix. These groups are preferably formed by thermal cleavage, but may be present before thermal cleavage has taken place. For example, polymers containing free carboxylic acid groups before thermal cleavage has taken place may be used. However, such polymers (for example poly(3-carboxydithiophene) (P3CT) and poly(carboxyterthiophene-co-diphenylthienopyrazine) (P3CTTP)) are typically not soluble in organic solvents.

Preferably, the hole conducting polymer is soluble in at least one organic solvent before thermal cleavage, and is substantially insoluble in organic solvents and neutral or non-basic water after thermal cleavage. This permits a robust, insoluble bulk heterojunction layer to be formed as well as permitting the layer to be formed using solution techniques.

In a preferred embodiment, the hole conducting polymer is a polythiophene (PT) or PPV substituted with ester groups (C═O—O—R) which cleave to give free carboxylic acid groups, for example 2-methylhexylcarboxylate ester groups. Tertiary ester groups are preferred as they are easily thermally cleaved, allowing lower temperatures to be used. Preferred hole conducting polymers are poly(3-(2-methylhex-2-yl)oxycarbonyldithiophene) (P3 MHOCT) and poly-[(3′-(2,5,9-trimethyldecan-2-yl)-oxy-carbonyl)-[2,2′;5′,2″]terthiophene-1,5″-diyl)-co-(2,3-diphenylthieno[3,4-b]pyrazine-5,7-diyl)] (P3TMDCTTP). The synthesis and thermal cleavage of the former polymer has been published in J. Am. Chem. Soc. 2004, vol. 126, p. 9486-9487 by Jinsong Liu et al. The synthesis and cleavage of the latter polymer is described below.

Other suitable substituents are thioesters which may cleave to give thioacids.

In an alternative embodiment, the hole conducting polymer is a polythiophene (PT) or PPV substituted with ester groups (C═O—O—R) which cleave to give free carboxylic acid groups, for example 2-methylhexylcarboxylate ester groups or trimethyl decan-2-yl ester groups, and which may then be further cleaved to remove at least some of the carboxylic acid groups. Preferred hole conducting polymers are poly(3-(2-methylhex-2-yl)oxycarbonyldithiophene) (P3MHOCT) and poly-[(3′-(2,5,9-trimethyldecan-2-yl)-oxy-carbonyl)-[2,2′;5′,2″]terthiophene-1,5″-diyl)-co-(2,3-diphenylthieno[3,4-b]pyrazine-5,7-diyl)] (P3TMDCTTP), which, when heated to around 300° C., undergo cleavage of the ester groups and subsequent loss of CO₂ to form polythiophene (PT) and poly(thiophene-co-diphenylthienopyrazine) (PTTP) respectively.

The polymers may be further substituted to alter their electronic properties with electron withdrawing or donating groups, or to alter their physical properties, such as solubility, for example with alkyl groups, or tertiary methoxyethoxyethoxy groups to convey solubility in water or ethanol. The choice of solubilising group is made according to the solvent employed during processing of the device films (i.e. organic or water miscible solvents). The solubilising chain is removed during thermocleavage and film processing and does not influence device performance at a later stage. The organisation of the molecules in the final film may show some dependence on the solubilising group.

A mixture of substituents may be used.

Preferably, the hole conducting polymer is unbranched.

The hole conducting polymer may be blended with a dye or a mixture of dyes. The hole conducting polymer may be a co-polymer, for example a block co-polymer.

In certain cases it may be preferred to use a regioregular polymer rather than a regiorandom polymer.

Preferably, the second electrode is reflective. This increases the efficiency of the device.

Preferably, the second electrode is formed of a highly conductive layer that may distribute charge over the whole of its surface. Preferably, the second electrode has a work function chosen with reference to the work function of the first electrode. Preferably, the difference between the work functions of the two electrodes is at least 0.0-3.0 eV, such as 0.0-1.0 eV. It is possible for the two electrodes to have the same work function, or to be identical.

Suitably, where the second electrode comprises a metal layer as the highly conductive layer, it is formed by coating of a dispersion of metal particles to form a thin layer.

Preferably, the second electrode comprises silver. This provides a relatively water and oxygen stable outer layer for the device, in comparison with conventionally used more reactive metals such as aluminium.

A layer of silver may be preferably formed, in view of the aims of the present invention, by application of a polymer dispersion of silver or a thermosetting screen printing silver paste in order to avoid expensive conventional vacuum deposition methods. The dispersion may be applied using spin coating, pad printing, doctor blading, casting, screen printing, roll coating or using a paint brush. This last technique has the advantage of allowing the electrode to be shaped as desired. The silver polymer layer may then be thermoset. Suitable conditions are heating at 140° C. for 3 minutes.

It is found that the device constructed in this fashion is robust. In particular, the second electrode formed as described above is scratch-resistant and much less prone to short circuits than conventional vapour deposited electrodes.

It may be advantageous in certain embodiments of the device if the transparent first electrode is the cathode. This avoids the use of low work function metals as electrodes. As such low work function metals are generally highly reactive with water and oxygen in the ambient environment, avoidance of their use improves the stability of the device. It should be noted that reversal of the polarity of the first and second electrodes does not necessarily require the reversal of the order of the metal oxide and bulk heterojunction layers. In particular, both electrodes may be formed from PEDOT-PSS, with the metal oxide and bulk heterojunction layers being arranged in either possible order in the cell.

Preferably, the photovoltaic cells are solar cells. However, the cells may also be electroluminescent devices.

Suitably, the module or the individual cells further comprise a UV filter. However, this feature is not necessarily preferred. The present inventors have found that, in certain cases at least, the presence of a UV filter leads to faster degradation of the performance of the cells, although also to higher values of I_{SC}.

In a second aspect is provided a method of making a photovoltaic cell module comprising a plurality of serially connected photovoltaic cells on a common substrate, comprising the steps of:

(a) forming a first electrode layer for each cell on the common substrate;
(b) printing a light-harvesting layer for each cell over the first electrode layer;
(c) printing a second electrode layer for each cell over the light-harvesting layer such that the second electrode layer of a first cell forms an electrical contact with the first electrode layer of an adjacent second cell without forming an electrical contact with the first electrode of the first cell or the light-harvesting layer of the second cell.

Preferably, the first electrode layers of each cell are coplanar and the light-harvesting layers of each cell are coplanar.

Preferably, the first electrode layers of each cell of the module are formed simultaneously, the light harvesting layers of each cell of the module are formed simultaneously, and the second electrode layers of each cell of the module are formed simultaneously.

Preferably, more than one module is simultaneously formed on the common substrate.

Preferably, the first electrode is formed by printing. Suitable methods are described above for the first aspect of the invention. Alternatively, a single layer of PEDOT:PSS may be printed as the conducting electrode. An ITO electrode can be formed with difficulty by printing, and so this is not a preferred substance for use as a printed first electrode.

Preferably, the photovoltaic cell module is a solar cell module.

Preferably, a charge transport layer is formed between at least one of the electrodes and the light harvesting layer. Suitably, an electron transport layer and/or a hole transport layer may be provided. Preferably, an electron transport layer is formed by providing a layer of metal oxide nanoparticles on the electrode, wherein the metal oxide is selected from the group consisting of: TiO₂, TiOₓ and ZnO. TiOₓ is used herein to denote a sub-stoichiometric oxide of titanium. Preferably, the metal oxide nanoparticle layer is formed by application of a layer of a solution of metal oxide nanoparticles to the electrode layer. The solution may be applied by spin coating, doctor blading, casting, screen printing, pad printing, knife over roll printing, slot-die printing, gravure printing or ink jet printing. Preferably, the nanoparticle layer is annealed after application. Suitably, this may be carried out by heating at 210° C. for 2 min, or in the case of flexible plastic substrates such as PET for 140° C. for at least 1 hour and preferably for 16 hours.

Preferably, the metal oxide is zinc oxide. This is advantageous as zinc oxide nanoparticles are readily soluble and may be processed into thin films at low temperatures.

Suitably, the zinc oxide nanoparticle solution may be stabilised by the addition of acids, amines, thiols or alcohols, for example, methoxyacetic acid, methoxyethoxyacetic acid, methoxyethoxyethoxyacetic acid, propylamine, octylamine, or octylthiol.

Preferably, a hole transport layer is formed by providing a hole conducting polymer layer, such as those described above for the first aspect of the invention, on the electrode. Preferably, the hole transport layer is provided adjacent the second electrode and the electron transport layer is formed on the first electrode.

Suitable light harvesting layers are described above for the first aspect of the invention.

Preferably, where both an electron transport layer and a hole transport layer are provided, the light-harvesting layer of each cell is formed by providing, between the charge transport layers, a bulk heterojunction layer comprising metal oxide nanoparticles and a hole conducting polymer containing thermocleavable groups, wherein the metal oxide is selected from the group consisting of: TiO₂, TiOₓ, CeO₂, Nb₂O₅ and ZnO, and subsequently heating the bulk heterojunction layer to cleave the thermally cleavable groups to produce an insoluble hole containing polymer. Preferably, the thermally-cleavable groups are the alkyl groups of an ester.

Suitably, the formation of the charge transport layers and the light harvesting layer may be performed more than once between the formation of the first and second electrodes. Each time the formation of the charge transport layers and the light harvesting layer is performed, a different selection of metal oxide and of components of the bulk heterojunction layer may be made. Suitably, the selection of the metal oxide and components of the bulk heterojunction layer may alternate between two choices between each formation of the charge transport layers and the light harvesting layer. Cells constructed in this fashion are known as tandem cells.

The advantage of tandem cells is that they may harvest more light than a single cell. Suitably, two polymers harvesting light at different wavelength ranges may be employed in the bulk heterojunction layer of each cell forming the tandem cell. For example, P3CT may be used as the hole conducting polymer in one cell and P3CTTP as the hole conducting polymer in the adjacent cell. In this case P3CT harvests light up to around 600 nm and passes all light at longer wavelengths. The P3CTTP harvests light up to about 950 nm. In principle, such cells will have a higher efficiency for this reason. In order to maximise the energy obtained, the current generated by each cell must be matched since the cells are placed in series.

It is necessary to carry out the heating of the bulk heterojunction layer each time that layer is formed and before the subsequent charge carrier layer is deposited. This ensures that the deposition of further layers cannot affect the integrity of the bulk heterojunction layer, as the bulk heterojunction layer is made insoluble by the thermal treatment. This is a significant advantage of the present method compared with prior art methods of manufacturing tandem cells.

In addition, between each formation of the charge transport layers and the light harvesting layer, it is usual when constructing such tandem cells to include a further layer between the hole transporting layer of one cell and the electron transport layer of the subsequent cell, which layer comprises a metal. This layer is said to function as a recombination layer, and has previously been believed to be essential in tandem cells. However, this layer has various disadvantages. It must be a very thin layer of metal in order to allow the passage of light therethrough. Thus, vacuum deposition of the layer is usually used, and, as explained above, that is not preferred for reasons of expense. Further, even where the metal layer is made to be very thin, the transparency of the layer is not high and the layer may reflect a proportion of the light entering the cell. This is not preferred as the cell loses efficiency if light does not reach the lower layers. The present inventors have discovered that this recombination layer is not essential to the function of the tandem cell, and indeed, when applied in tandem cells according to the present invention, is found to reduce their performance.

Suitably, the formation of the electron transport layer, light-harvesting layer and hole transport layer can be carried out in that order or in the reverse order.

Suitably, the bulk heterojunction layer may be provided on a metal oxide electron transport layer by coating a solution of the metal oxide nanoparticles and hole conducting polymer onto the metal oxide layer followed by removal of the solvent. Coating may be carried out by spin coating or screen printing a solution of the hole conducting polymer, or by the use of a doctor blade.

Suitable solvents include any organic or inorganic solvent: examples include chlorobenzene, chloroform, dichloromethane, toluene, benzene, pyridine, ethanol, methanol, acetone, dioxane, tetralines, xylenes, dichlorobenzene, tetrahydrofuran, alkanes (pentane, hexane, heptane, octane etc.), water (neutral, acidic or basic solution) or mixtures thereof. To the solution, small amounts of a suitable polymer (for example, polystyrene or polyethylene glycol) may be added to adjust the viscosity.

Suitable solvents also include thermocleavable solvents such as those described in WO2007/118850. These solvents have the advantage that, while not being volatile in themselves, they may be thermally cleaved to give more volatile products that may be easily removed from the bulk heterojunction layer. When forming the bulk heterojunction layer by screen printing, it is preferred to use these thermocleavable solvents.

Where the metal oxide used is ZnO, and it is intended to coat an aqueous solution on to the bulk heterojunction layer in order to form a subsequent layer, the ratio of ZnO:polymer in the solution is preferably at least 1:1 but preferably around 2:1 (w/w) and in the range 1:1 to 4:1. This permits a solution used to form the second electrode to wet the surface of the bulk heterojunction layer efficiently, improving the formation of the second electrode. A lower proportion of ZnO in the layer results in poor wetting. However, if using an organic solvent based screen printing formulation, wetting is not a problem, and the above ratios are not required.

There are various considerations which determine the optimum thickness of the light harvesting layer.

An exciton is generated at the spot where a photon is absorbed. This occurs throughout the light harvesting layer, but mostly close to the transparent electrode. In order to generate electricity, the exciton has to reach a dissociation location (for example the electrode surface, or the light harvesting layer/charge transport layer interface) and the charge carrier has to reach an electrode (holes and electrons go to opposite electrodes).

The thicker the light harvesting layer, the more likely photon absorption is to take place. A certain thickness is required in order to absorb sufficient light. A thickness giving an absorbance of around 1 (this corresponds to 90% absorbance of the light) is preferable. This was found to be achieved when a solution having a concentration of 25 mg·ml⁻¹ of P3 MHOCT and from 10-50 mg·ml⁻¹ of ZnO nanoparticles in chlorobenzene was used to form a bulk heterojunction layer.

However, if the thickness is too high the average distance that an exciton or a charge carrier (a hole or an electron), has to diffuse becomes too long, because of the possibility that the exciton will recombine and produce heat, or that a free hole will meet a free electron and recombine.

The optimum thickness also depends on manufacturing considerations. Some techniques give thick films and others give thin films. It is possible to form thick layers of the bulk heterojunction described above by repetition of the film deposition and thermocleavage step to build up a layer of the desired thickness. This is of particular interest where a layer is desired of greater thickness than is obtainable by, for example, a single spin coating, or where a method of layer formation is used that is prone to the formation of defects. For example, in screen printing the film quality can be lower in the sense that there are sometimes point defects, which may lead to short circuit of the device. As a practical solution to this a second print generally does not generate the point defect in the same spot. Therefore it is advantageous when screen printing films to make a layer from more than one screen printing step. The present inventors have found that the use of the thermocleavable solvents in WO2007/118850 allows screen printing to be used to construct photovoltaic devices very successfully.

As the film thickness increases, the chance of film defects (holes that allows the two electrodes to touch) leading to a short circuit decreases.

Taking all these factors into consideration, it is preferred for the light harvesting layer to have a thickness of at least 10 nm. Preferred thicknesses are in the range of 30 nm to 300 nm, for example about 100 nm. If a multilayer structure is adopted, such as in a tandem cell, a larger range of thicknesses can be accommodated. For example, in a tandem cell, each active layer thickness is in the range of about 30-300 nm. In addition to this is the thickness of the metal oxide and the hole transporting layers. This means that the entire thickness of the tandem device is in the range of 100-1000 nm.

Preferably, heating of the bulk heterojunction layer in order to thermocleave the hole conducting polymer is carried out at a temperature between 50 and 400° C., more preferably between 100 and 300° C., for example at a temperature of 210° C. The temperature must not be too high because at high temperatures the polymer and/or electrode material may start to degrade. Also, the temperature should be chosen with reference to the chosen starting material and the product to be obtained on thermocleavage.

Suitably, the heating may be carried out using a laser in the wavelength range 475-532 nm in order that the bulk heterojunction layer is heated without overheating of the underlying layers and the substrate. Alternatively, a high power LED light source can be employed where a wider range of wavelengths are available 450-550 nm are easily covered.

Suitably, heating may carried out in at atmosphere without oxygen or with reduced oxygen, for example under an inert atmosphere or in a vacuum oven. This helps to prevent degradation of the polymer and/or electrode. However, the heating may be carried out without these precautions with only a slight loss in performance to the eventual device, and, with the aim of simplification of manufacture and reducing cost in mind, it is preferred not to use inert atmosphere or vacuum.

Preferably, the method comprises the additional step of maturing the device in the dark before use. This leads to an increase in performance compared with the freshly-made device. A suitable period of time for maturation is 24-72 h. Preferably, the device is matured for at least 72 h. It is found that this time period permits the majority of the improvement in performance resulting from the maturation to be obtained.

Preferably, the electron transport layer, bulk heterojunction layer, hole transport layer and second electrode layer are all formed by screen printing. Suitably, the electron transport layer and the bulk heterojunction layer may be screen printed as solutions in a thermocleavable solvent.

In a third aspect, the present invention provides a photovoltaic cell module comprising a plurality of photovoltaic cells in the form of serially-connected nested loops each having a substantially identical light-harvesting area. Preferably, the cells are located on a common substrate. Suitably, each of the photovoltaic cells is in the form of a closed loop. However, in some circumstances it may be preferred that each of the cells is in the form of an open loop, such as a horseshoe shape. Suitably, the loop may be circular or part circular, although the use of polygonal or part polygonal loops is also envisaged. Suitably the nested loops may be concentric.

Preferably, the light harvesting layer comprises a conducting polymer. Preferably, the light harvesting layer comprises a mixture of a conducting polymer and metal oxide nanoparticles. Preferably, the metal oxide is selected from the group consisting of: TiO₂, TiOₓ, CeO₂, Nb₂O₅ and ZnO.

Preferably, each cell further comprises an electron transport layer comprising metal oxide nanoparticles adjacent the first electrode and a hole conducting layer adjacent the second electrode.

Preferably, each cell comprises:

(a) a first electrode;
(b) an electron transport layer which is a metal oxide nanoparticle layer, wherein the metal oxide is selected from the group consisting of: TiO₂, TiOₓ and ZnO;
(c) a bulk heterojunction layer comprising metal oxide nanoparticles and a hole conducting polymer which has been thermally treated to decrease its solubility, wherein the metal oxide is selected from the group consisting of: TiO₂, TiOₓ, ZnO, CeO₂ and Nb₂O₅;
(d) a hole transporting layer; and
(e) a second electrode.

Preferably, the photovoltaic cell module is a solar cell module.

In a fourth aspect, the present invention provides an item comprising a photovoltaic device according to the first or third aspect of the present invention, a power consuming device and/or power storing means. Suitably, the power consuming device may be a radio. Suitably, the power storing means may be a rechargeable battery. Suitably, the item may be a hat.

A general description of the function of the layers of the cells of a preferred embodiment of the invention is provided below:

Electrode layers: One of the electrodes is necessarily transparent and both electrodes may be transparent. Typically, the first electrode is the front electrode and therefore it is transparent. The back electrode does not need to be transparent. The purpose of the front electrode is to admit light to the device film. The first electrode may be a pure transparent conductor (ITO, TCO, PEDOT) or it may be a composite of a conducting metal grid allowing from some light to come through with a conducting polymer on top (such as PEDOT:PSS, PEDOT:PTS, polyprodot, polyaniline, polypyrrole or other similar conducting polymers known in the art).

The metal oxide layer functions as an electron transporting layer. The metal oxide layer is placed on top of the first electrode. The metal oxide layer is optically transparent (no colour) and only transports electrons.

Active layer: this comprises a hole conducting polymer and dispersed metal oxide nanoparticles in a bulk heterojunction. In this layer light is absorbed to form an exciton, and the exciton dissociated to a hole and an electron that can percolate through the interpenetrating network of polymer and oxide. The holes are transported in the polymer and the electrons are transported in the oxide.

On top of the active layer PEDOT:PSS or a similar conducting polymer is employed as a hole transporting layer.

Second/back electrode: Any highly conducting material such as a metal. The purpose is to remove the charges as efficiently as possible.

Explanation of the working of the device: The charges generated in the active layer can diffuse round in the two interpenetrating networks (holes in the polymer network and electrons in the oxide network). However electrons can only leave through the oxide layer and holes can only leave through the hole transporting layer. Thus, an electrical potential difference is created between the two electrodes.

The cells may be realised in reverse order.

Tandem cells: When stacking cells the holes coming through the hole transporting layer from the first cell meet the electrons in the metal oxide layer coming from the next cell and recombine. The result is that the voltage of the first and the second cell are added. However if the first and the second cell do not produce roughly the same amount of charge some charges are lost in the recombination layer between the first and second cell, i.e. some of the holes or electrons will not find a partner to recombine with.

Features described in connection with any aspect of the invention can also be applied to any other aspect of the invention.

### BRIEF DESCRIPTION OF THE FIGURES

FIG. 1 shows the construction of a photovoltaic cell module according to both the first and third aspects of the invention. FIG. 1A shows a cross section of the device. FIG. 1B shows an exploded diagram of the mask patterns used for the printing of each layer of that device.

FIG. 2 shows the masks used for printing (A) the electron transport layer, (B) the light harvesting layer, and (C) the hole transport layer and the second electrode layer of the device of FIG. 1.

FIG. 3 shows a photograph of four printed circular solar cell modules, each having a concentric arrangement of cells, with a structure corresponding to that shown in FIG. 1A.

FIG. 4 shows an alternative structure for the photovoltaic module of the inventions, in which the cells are formed as open loops.

FIG. 5 shows a schematic diagram of the layers of a cell that may be incorporated into a module according to the present invention.

FIG. 6 shows a schematic diagram of the layers of a tandem cell that may be incorporated into a module according to the present invention.

FIG. 7 shows a hat comprising a solar cell according to the invention connected to a radio with earphones.

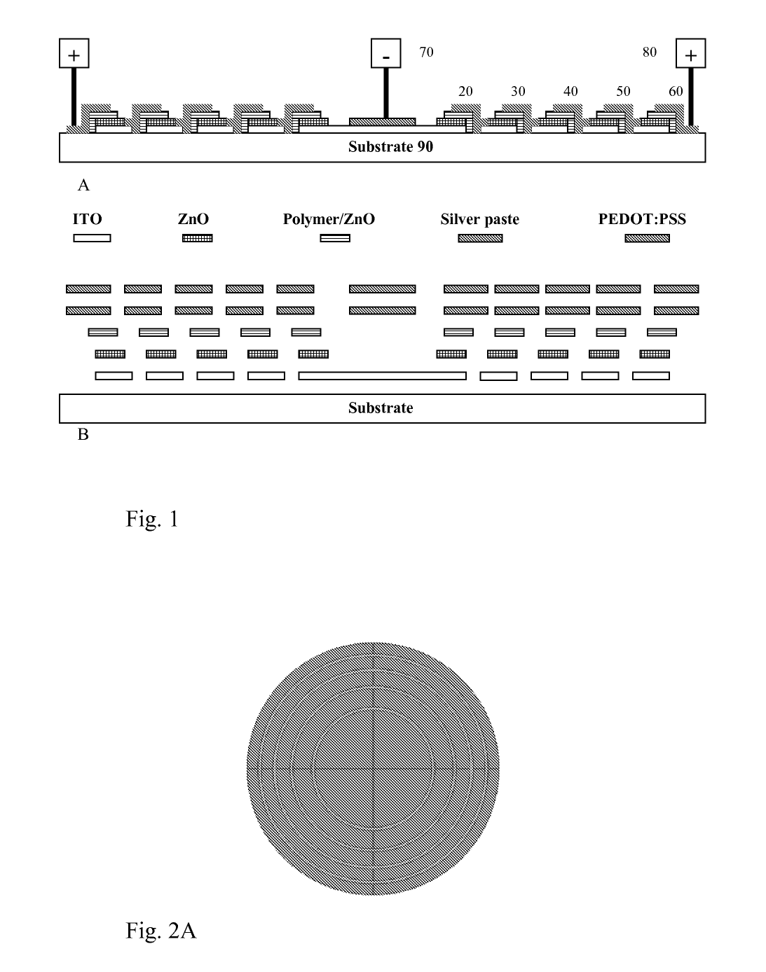

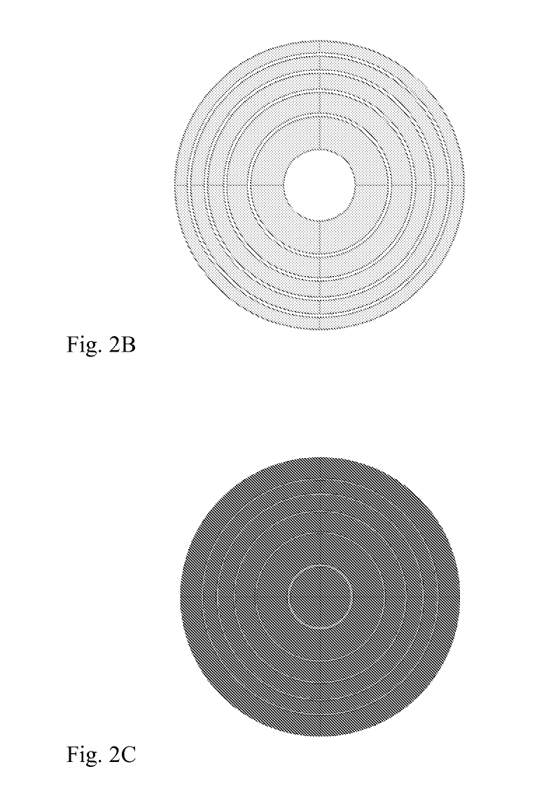

Referring to FIG. 1, the photovoltaic cell module comprises serially-connected photovoltaic cells 20, 30, 40, 50 and 60, and central cathode 70 formed on common substrate 90, which may be of a plastics material or of glass. A first electrode layer of ITO is deposited on substrate 90, photoresist is applied through the mask as shown in FIG. 2A and the layer etched to provide a pattern of first electrode layers for each cell (shown in white), with the electrode layer of the inner cell extending also to the cathode 70. A solution of zinc oxide nanoparticles (shown in cross-hatching) is then applied to the first electrode layer by screen printing through a mask whose alignment with the first electrode layer is shown in FIG. 1B, and dried to create the zinc oxide electron transport layers of each cell. A solution of hole conducting thermocleavable polymer, such as P3MHOCT, and ZnO nanoparticles is then applied by screen printing through a mask as shown in FIG. 2B and whose alignment with the ZnO layer is shown in FIG. 1B. The polymer layer is then heated to thermocleave the ester groups from the P3MHOCT and convert it to the insoluble P3CT to create light harvesting layers (shown in horizontal stripes). It will be seen from FIG. 1A that the light-harvesting layer is allowed to extend past the outer edges of the subsidiary zinc oxide and first electron layers, thus preventing electrical contact between the second electrode layer and the first electrode layer of the same cell. A solution of PEDOT:PSS followed by a silver paste, are sequentially applied by screen printing through a mask as shown in FIG. 2C and whose alignment with the previous layers is shown in FIG. 1B, forming the hole transport and second electrode layers jointly and also a layer to act as a contact for cathode 70 (all shown in grey). It can be seen from FIG. 1A that the second electrode layer of each but the outer cell (i.e. cells 20, 30, 40 and 50) forms an electrical contact to the first electrode layer of the outerward adjacent cell (i.e. cells 30, 40, 50 and 60), but that the second electrode layer is aligned such that no contact between it and the second electrode layers of adjacent cells is made. Anode 80 is formed on the second electrode layer of the outermost cell 60. It will of course be appreciated by the skilled reader that the arrangement shown in FIG. 1A is a schematic diagram, and so the layer thicknesses are not shown to scale and the exact form of the printed layers in the actual device may vary from that depicted.

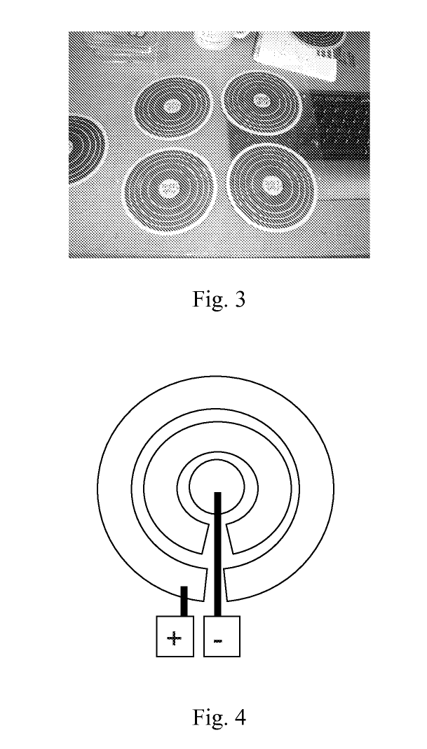

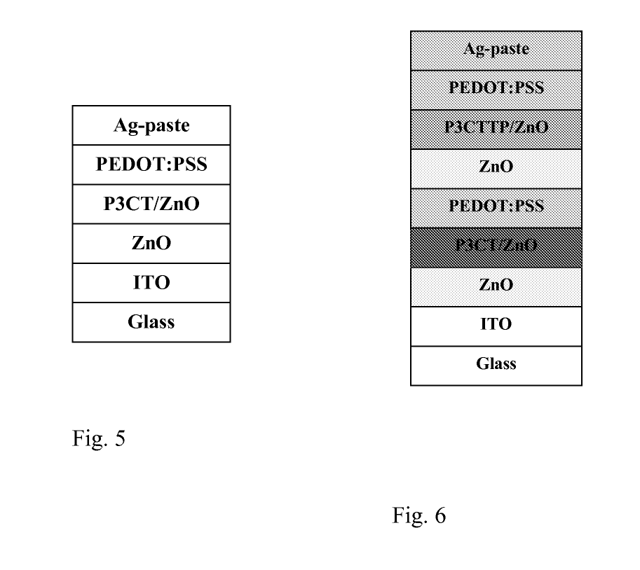

A photograph showing four photovoltaic modules of the invention formed on a common transparent substrate is shown in FIG. 3. The modules are viewed through the transparent substrate, and the red colouring of the concentric rings is due to the light-harvesting layer containing P3CT. The white colouring is due to the silver second electrode layer, with the outer white ring forming the anode and the inner white ring forming the cathode. It can clearly be seen from this photograph, and from the masks in FIG. 2, that the outer rings are narrower than the inner rings. This is because the active area of each cell is the same, in order that the photons incident on the device are used as efficiently as possible, as explained in more detail above.

The modules do not require encapsulation in order to function efficiently or to gain operational stability but a mechanical barrier to protect the silver back electrode may be desirable. In the case of this application the modules were laminated using a thin PET (100 micron) film and the electrical contacts were made afterwards to the inner and the outer ring by simply crimping a standard metallic thin film crimp connector whereto electrical leads could be soldered. The modules were lasercut to their circular shape. Both methods (lamination and contacting) were chosen as they are compatible with serial production of the device modules.

FIG. 4 shows an alternative arrangement of a photovoltaic module according to the invention. In this embodiment, the cells are formed as open part-circular loops, in order to accommodate the printing of a conductor leading from the central cathode to the outer edge of the device.

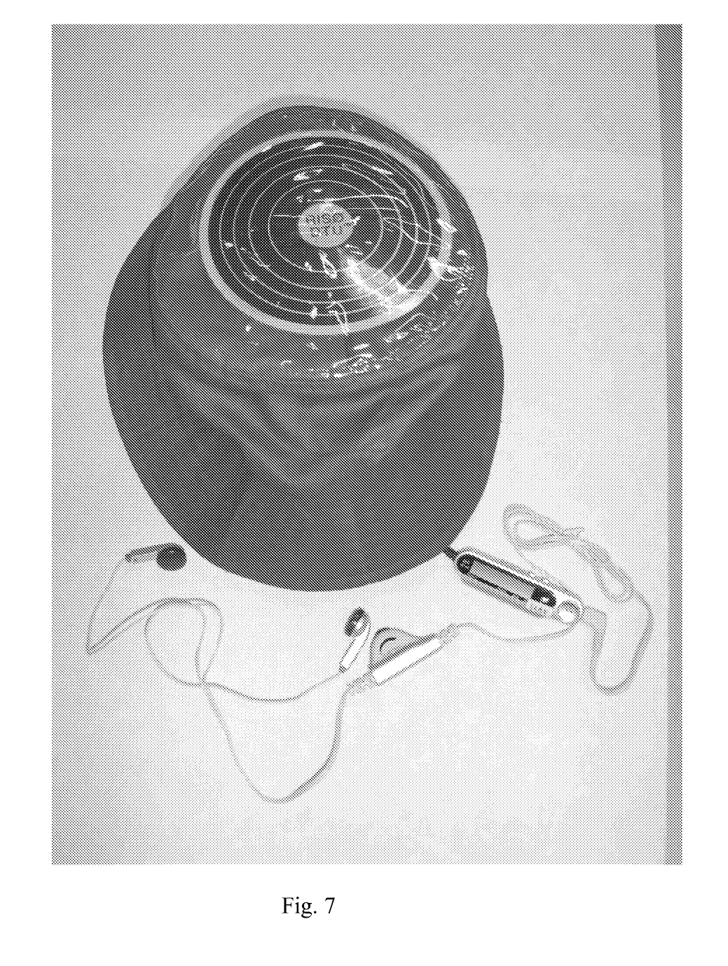

Referring now to FIG. 7, a solar cell module was placed in a pocket on the top of the hat with the active side exposed through a transparent plastic front. The module powered a small radio that typically consumed 1.7V and 3.8 mA of current with normal volume setting and up to 6 mA at maximum volume setting. The system comprises a small charger and a backup battery to buffer the operation in case the solar cell module was covered temporarily.

### EXAMPLES

### General Methods

Regiorandom poly(3-(2-methylhex-2-yl)-oxy-carbonyldithiophene) (P3MHOCT) was synthesised by the method of Jinsong Liu et al. (J. Am. Chem. Soc. 2004, vol. 126, p. 9486-9487). The synthesis is outlined below:

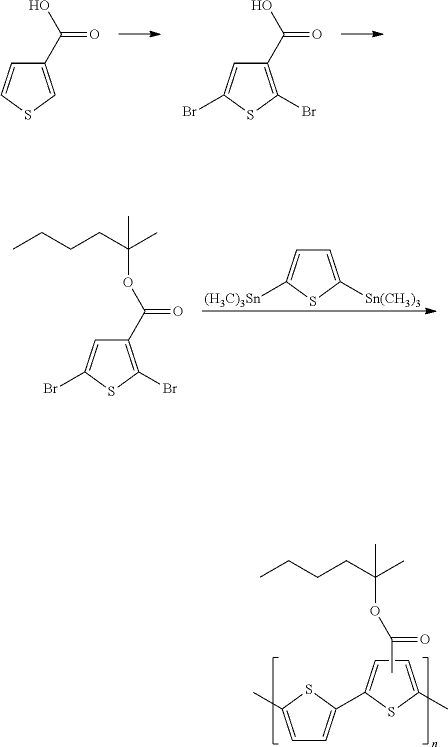

The P3MHOCT as synthesised had the following properties: Mₙ=11600 g·mol⁻¹; M_{w}=28300 g·mol⁻¹; Mₚ=27500 g·mol⁻¹; PD=2.6. The P3MHOCT was used as a solution in chlorobenzene, prepared by gentle shaking at room temperature. The use of elevated temperature was avoided in this step. The solution was stable for extended periods in a glove box or tightly sealed container.

P3TMDCTTP was synthesised as set out below:

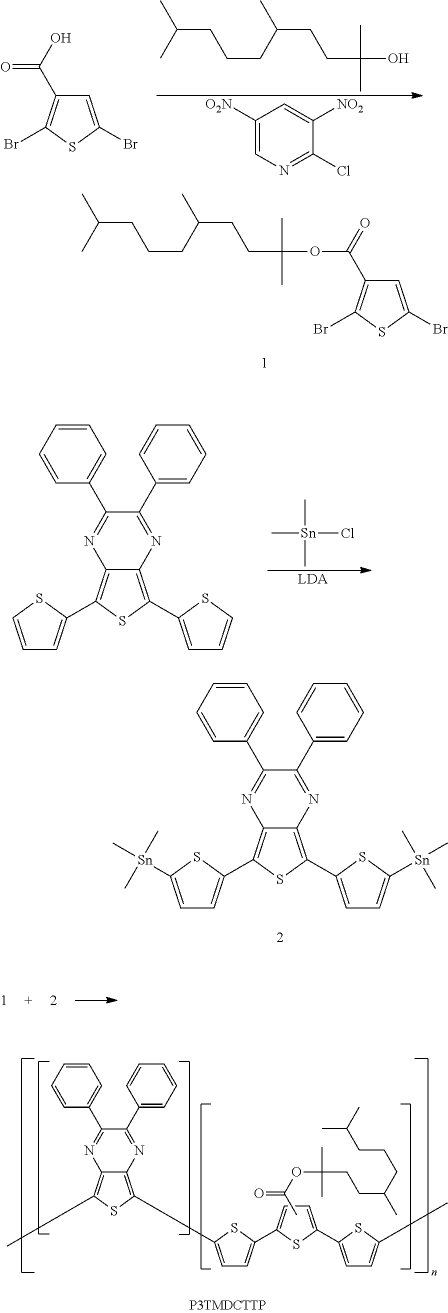

Synthetic procedure to the thermocleavable low band gap polymer P3TMDCTTP.

### Synthesis of (2,5,9-trimethyldecan-2-yl)-2,5-dibromothiophene-3-carboxylate

2,5-Dibromothiophene-3-carboxylic acid (10.0 g, 35 mmol) and 2-chloro-3,5-dinitropyridine (7.8 g, 38.5 mmol 1.1 eq.) was dissolved in dry pyridine under argon. The mixture was heated to approx. 40° C. for 30 minutes. 2,5,9-Trimethyl-decan-2-ol (7.7 g 38.5 mmol 1.1 eq) was added and the mixture is stirred at 120° C. overnight. After cooling to ambient temperature, the mixture was poured into a mixture of water (300 mL), light petroleum (300 mL) and NaHCO₃(aq) (100 mL, 2M). The aqueous phase was extracted with light petroleum (3×100 ml), and the combined organic phases were dried over MgSO₄ and evaporated to give a light yellow oil. The product was purified by flash chromatography using heptane as base solvent and extracting the desired product with 2% ethyl acetate to give a colourless oil. Yield: 5.1 g (34%). ¹H NMR (CDCl₃): δ: 0.88 (t, 9H, J=7 Hz), 1.09-1.32 (m, 8H), 1.35-1.44 (m, 2H), 1.56 (s, 6H), 1.80-1.92 (m, 2H), 7.29 (s, 1H). ¹³C NMR (CDCl₃) δ: 19.7, 22.6, 22.7, 24.8, 26.1, 26.2, 28.0, 30.8, 33.0, 37.1, 38.2, 39.3, 85.0, 110.9, 118.0, 131.9, 133.4, 159.9.

### Synthesis of 2,3-diphenyl-5,7-bis(5-(trimethylstannyl)thiophen-2-yl)thieno[3,4-b]pyrazine

A solution of LDA was prepared as follows: THF (10 mL) was cooled to −10° C. and n-BuLi (1.6 M, in hexane, 10 mL, 16 mmol) was added dropwise. The mixture was stirred for 10 min. and di-isopropylamine (2.5 mL, 18 mmol) in THF (7.5 mL) was added drop wise. The mixture was stirred for 30 min. at −10° C. and used directly. LDA solution (20 mL, 11 mmol, 5 eq.) was added drop wise to a solution of 2,3-diphenyl-di-thiophen-2-yl-thieno(3,4-b)pyrazine (1.0 g, 2.2 mmol) in THF (50 mL) at −78° C. A colour change from green to dark purple was observed. After 1 hour at −78° C. (2.6 g, 13 mmol) of trimethylstannyl chloride dissolved in dry THF (7 mL) was added over a period of 5 min. After the mixture had reached ambient temperature it was evaporated to dryness and recrystallized from heptane, to give a purple solid. Yield: 1.1 g (64%). ¹H NMR (CDCl₃): δ: 0.44 (s, 18H), 7.22 (d, 2H, J=4 Hz), 7.33-7.40 (m, 6H), 7.62 (dd, 4H, J1=8 Hz, J2=1 Hz), 7.87 (d, 2H, J=4 Hz). ¹³C NMR (CDCl₃) δ: −8.2, 124.9, 126.1, 128.0, 128.9, 130.0, 135.6, 137.5, 139.2, 139.7, 140.2, 152.7

### Synthesis of Regiorandom poly-[(3′-(2,5,9-trimethyldecan-2-yl)-oxy-carbonyl)-[2,2′;5′,2″]terthiophene-1,5″-diyl)-co-(2,3-diphenylthieno[3,4-b]pyrazine-5,7-diyl)] (P3TMDCTTP)

2,3-diphenyl-5,7-bis(5-(trimethylstannyl)thiophen-2-yl)thieno[3,4-b]pyrazine (300 mg, 0.3854 mmol) and (2,5,9-trimethyldecan-2-yl)-2,5-dibromothiophene-3-carboxylate (180.5 mg, 0.3854 mmol) were dissolved in dry toluene under argon, Pd₂dba₃ (12.5 mg,) and Tri-t-butylphosphonium tetrafluoroborate (25 mg) were added. N-methyldicyclohexyl amine (0.5 ml) was added after 5 min. The mixture was refluxed for 4 days. The mixture was concentrated to half the original volume on a rotary evaporator in vacuum and the residue was poured into 5 volumes of methanol. The precipitate was isolated by filtration, washed with methanol and dried to give a dark green powder. Yield: 198 mg (67%). ¹H NMR (CDCl₃): δ: 0-79-0.86 (m, 9H), 1.05-1.35 (m, 10H), 1.50-1.60 (m, 6H), 1.74-1.90 (m, 2H), 7.30-7.50 (m, 9H), 1.51-1.73 (m, 6H). SEC: Mₙ=1800, M_{w}=2900, Mₚ=2500, PD=1.6.

Films of P3TMDCTTP may be converted to P3CTTP by heating at 210° C. for 2 min. The conversion is associated with a distinct change in color from a clear green to a more pale tone. Heating of P3TMDCTTP at 310° C. causes conversion to PTTP by loss of both the ester alkyl group and the carboxylate functionality.

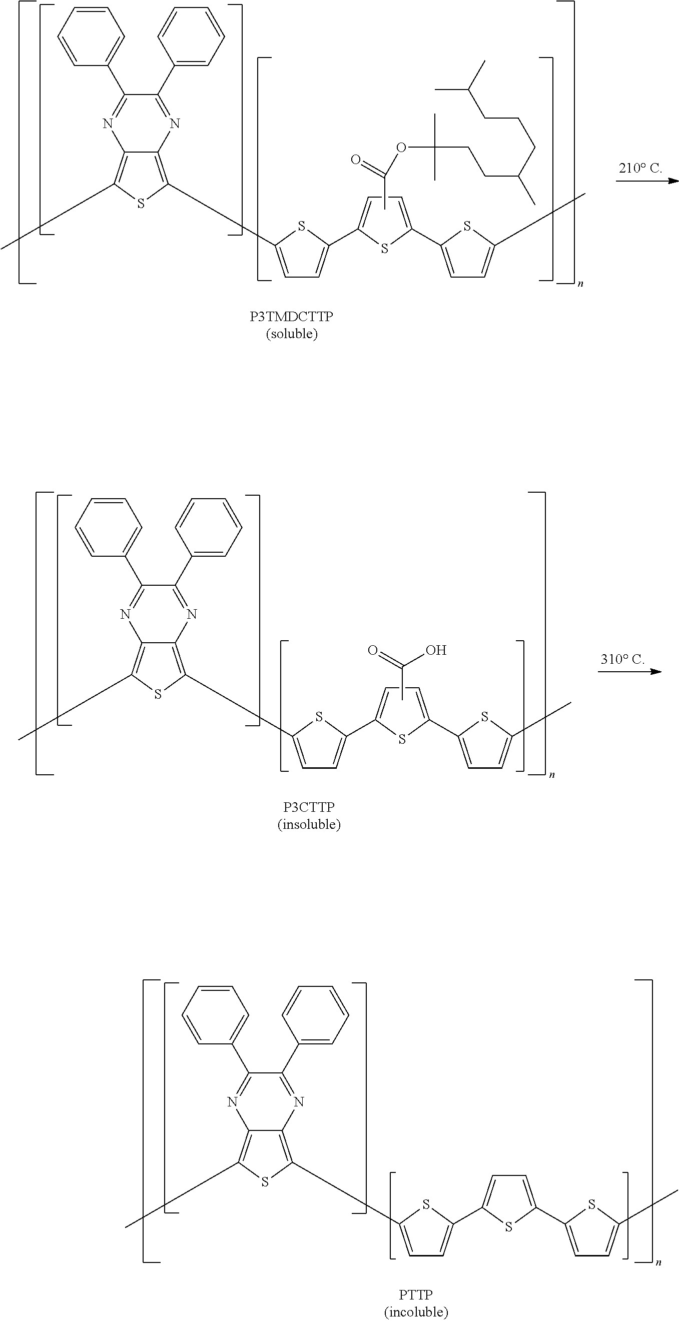

Aqueous PEDOT-PSS was purchased from Aldrich as a 1.3 wt % aqueous solution and used as received.

PEDOT:PSS for screen printing was purchased from Agfa (Orgacon 3000 and 5000 series, specifically tested Orgacon 3040, and 5010).

Glass substrates with a 100 nm layer of ITO and a sheet resistivity of 8-12 Ω·square⁻¹ were purchased from Delta technologies and cleaned by consecutive ultrasonication in acetone, water and isopropanol for 5 min followed by drying immediately prior to use.

Alternatively, an aluminium/PEDOT:PSS composite electrode may be prepared as follows:

A 100 nm thick layer of aluminium was applied to the substrates by thermal evaporation at a pressure<1.10⁻⁶ mBar. Standard ORDYL 940 photonegative photoresist (4615 from www.megauk.com) was applied by cold lamination onto the substrate with an evaporated aluminium electrode. The photoresist was illuminated for 45 s through a photonegative mask of the anode grid pattern consisting of parallel lines with a thickness of 250 μm and a spacing of 500 μm. The geometric fill factor of the anode was thus 50%. The resist was developed (developer for 4615 from www.megauk.com) and etched carefully in 10% HCl(aq) containing FeCl₃ (5% wt/V) until the aluminium at the exposed area had dissolved. Then the resist was removed by subjecting the substrates to ultrasound in ethanol whereby the photoresist detaches efficiently within 5 minutes The substrates with the aluminium pattern were washed with ethanol and dried at 25° C. for 10 minutes before optional application of a thin semi-transparent silver layer (5 nm) by evaporation followed by the PEDOT:PSS layer by spin coating at 2800 rpm.

For the back electrode a silver migration resistant polymer based on Dupont 5007 and capable of being cured at 130-140° C. for 3 minutes was used.

Zinc oxide nanoparticles were prepared by a procedure similar to that reported in Beek et al., J. Phys. Chem. B 109 (2005) p 9505. In a 3-litre conical flask, Zn(OAc)₂.2H₂O (29.7 g) was dissolved in methanol (1250 ml) and heated to 60° C. with stirring. KOH (15.1 g) dissolved in methanol (650 ml) and heated to 60° C. was added over 30 s. The mixture becomes cloudy towards the end of the addition. The mixture was heated to gentle reflux and after 2-5 min the mixture became clear and was stirred at this temperature for 3 h during which time precipitation starts. The magnetic stirrer bar was removed and the mixture left to stand at room temperature for 4 h. The mixture was carefully decanted leaving only the precipitate. The precipitate was then resuspended in methanol (1000 ml) and allowed to settle for 16 h. The mixture was then decanted carefully making sure that as much of the supernatant was removed as possible without the precipitate becoming dry. Chlorobenzene (35 ml) was added immediately and the precipitated nanoparticles dissolved giving a total volume of 45 ml. The typical concentration of a solution prepared in this manner was 200 mg·ml⁻¹, depending on the loss of nanoparticles during decanting of the supernatant. As an alternative to decantation, centrifuging of the mixture in methanol may be used, and this allowed the isolation of higher and more consistent yields of nanoparticles; however, the nanoparticles dissolved less easily and in a lower concentration in chlorobenzene when prepared by this method. The final solution of ZnO nanoparticles in chlorobenzene typically contains 10-20% methanol as free solvent and as solvent bound to the zinc oxide nanoparticles. The concentration of the ZnO nanoparticles in solution was determined by evaporation of the solvent from 1 ml of the solution at 80° C. for 1 h followed by careful weighing. The solution was stable for extended periods in a glove box or a tightly sealed container.

Solutions of P3MHOCT or P3TMDCTTP and zinc nanoparticles in chlorobenzene were prepared by gentle shaking at room temperature, and were used within 24 h. Poorer results were obtained when older solutions were used. This is thought to be due to the basic nature of ZnO causing some hydrolysis of the ester groups of the polymer.

Resistivity of electrodes was determined using a four-point contact probe from Jandel (www.jandel.com) in conjunction with a Keithley 2400 Sourcemeter. The value sheet resistivity was obtained by passing a series of currents (low to high current) through the film. In order to avoid offsets in the sourcemeter and effects of thermovoltages the same level of current was passed in both directions. The sheet resistivity was determined from an intermediate current range where the resistivity is independent of the current.

### Example 1

### Preparation of a Photovoltaic Module Comprising Five Serially Connected Concentric Rings with Equal Light Area

A small module comprising 5 cells in series was realised on a flexible plastic (polyethyleneterephthalate, PET) substrate with an overlayer of ITO that had been etched to match the 5 active areas of the device.

ZnO nanoparticles were prepared as a 50 mg mL⁻¹ solution in the thermocleavable solvent 2,5-dimethylhexyloxy-phenyloxy-carbonate (WS-1) (WO2007/118850). The solution was prepared by adding to WS-1 a stock solution of ZnO nanoparticles (200 mg mL⁻¹) that had been stabilised with methoxyethoxy acetic acid (MEA) (40 mg mL⁻¹) in a 80:20 (v/v) solution of chlorobenzene and methanol. After mixing the chlorobenzene and methanol was evaporated giving the final solution of ZnO in WS-1.

This solution was screen printed onto the PET-ITO pattern such that the printed ZnO layer covered the ITO pattern. The screen printing was performed with a 140 mesh screen and the squeegee speed was 550 mm s⁻¹. The printing speed was not critical but faster speeds were preferred. The screen was tested in the range of mesh from 90-220 and was not critical but 140-180 mesh was preferred. The printed film was dried at 70° C. for 1 hour, 140° C. for 12 hours and left in the ambient air for 12 hours to become insoluble. The active layer was then printed as a solution in WS-1 that was 25 mg mL⁻¹ P3 MHOCT, 50 mg mL⁻¹ ZnO and 10 mg mL⁻¹ MEA. The solution was prepared by dissolving P3 MHOCT in chlorobenzene followed by microfiltering and mixing with MEA stabilised ZnO nanoparticles in WS-1. Evaporation of the chlorobenzene and methanol gave the final screen printing formulation that was screen printed as above through a 140 mesh screen with a squeegee speed of 550 mm s⁻¹. The printed pattern exposed the ITO in one end of each cell to allow for the serial connection later. The film was dried at 140° C. for 12 hours in order to thermocleave and evaporate the solvent and to convert P3MHOCT to P3CT (poly-(3-carboxydithiophene)) as shown below, which conversion may be observed by a colour change from burgundy to bright red, and by the loss of solubility of the layer in chlorobenzene. A second print was employed to reduce the effect of pinholes and short circuits.

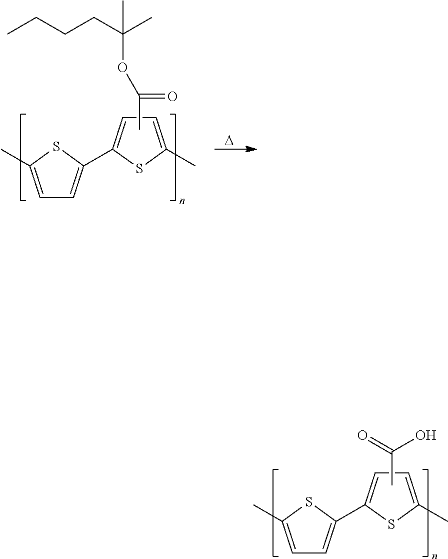

PEDOT:PSS (Orgacon 5010 from Agfa) was screen printed in a pattern matching the active layer on top and dried at 120° C. for 15 min.

Silver paste (Dupont 5007) was screen printed through a 120 mesh screen at a speed of 550 mm s⁻¹ in a pattern that defined the active area of the devices and connected to the ITO of the adjacent cell making a serial connection. The Ag paste was cured at 140° C. for 3 min. The device was ready to use and gave a voltage of typically 2.1-2.5 V and a short circuit density of 0.5-11 mA cm⁻². Devices with two prints of the active layer gave lower current densities but generally had a better voltage due to fewer short circuits.

Device Testing

The devices were illuminated in the ambient air using a solar simulator from Steuernagel Lichttechnik, KHS 575. The luminous intensity and emission spectrum of the solar simulator approaches AM 1.5 G and was set to 1000 W·m⁻² using a precision spectral pyranometer from Eppley Laboratories (www.eppleylab.com). The incident light intensity was monitored continuously every 60 s during the measurements using a CM4 high temperature pyranometer from Kipp and Zonen (www.kippzonen.com). Both instruments are bolometric. The variation in incident light intensity during the testing (150 h) was less than 5% and no corrections were made. No corrections for mismatch were made. IV-curves were recorded with a Keithley 24-sourcemeter from −1V to +1V in steps of 10 mV with a speed of 0.1 s·step⁻¹.

The dependence of the performance as a function of incident light intensity was carried out at a constant temperature of 72±2° C. in a non-transparent black box with an opening the at could be covered with an appropriate netral density (ND) filter) (Thorlabs Inc.). The incident light intensity was set to 1000 W·m⁻² without ND filter. ND filters with a transmission of 80%, 63%, 50%, 40%, 32%, 10%, 5% and 1% were each placed in front of a small test device prepared on a glass/ITO substrate. The active area was 1 cm². The device was prepared in a glove box using spincoating and the results represent the level of performance that can be achieved with this technology. The device and the short circuit current were recorded.

The efficiency was determined for the devices at 1 sun (1000 W·m⁻²) and gave V_{OC}=0.516, I_{SC}=1.00 mA·cm⁻², fill factor (FF)=0.35% and PCE=0.18%. At 0.1 sun (100 W·m⁻²) the values obtained were V_{OC}=0.530, I_{SC}=0.289 mA·cm⁻², fill factor (FF)=0.30% and PCE=0.46%. The performance is thus significantly better towards lower light intensities.

1. A photovoltaic cell module comprising a plurality of serially connected photovoltaic cells on a common substrate, each comprising a first electrode, a printed light-harvesting layer and a printed second electrode, wherein at least one of the electrodes is transparent, and wherein the second electrode of a first cell is printed such that it forms an electrical contact with the first electrode of an adjacent second cell without forming an electrical contact with the first electrode of the first cell or the light-harvesting layer of the second cell, wherein the photovoltaic cells are formed as nested loops.

2. The photovoltaic cell module according to claim 1, wherein the first electrode is transparent.

3. The photovoltaic cell module according to claim 1, wherein the substrate is transparent.

4. (canceled)

5. The photovoltaic cell module according to claim 1, wherein the photovoltaic cells each have a substantially identical light-harvesting area.

6. The photovoltaic cell module according to claim 1, in which, between at least one of the electrodes and the light-harvesting layer is provided a charge transport layer.

7. The photovoltaic cell module according to claim 6, wherein between one electrode and the light harvesting layer is provided a charge transport layer which is an electron transport layer, and between the other electrode and the light harvesting layer is provided a charge transport layer which is a hole transport layer.

8. The photovoltaic cell module according to claim 7, wherein the electron transport layer comprises metal oxide nanoparticles.

9. The photovoltaic cell module according to claim 8, wherein the metal oxide is selected from the group consisting of: TiO₂, TiOₓ and ZnO.

10. The photovoltaic cell module according to claim 7, wherein the hole transport layer comprises a hole conducting polymer.

11. The photovoltaic cell module according to claim 10, wherein the hole conducting polymer is PEDOT.

12. The photovoltaic cell module according to claim 7, wherein the electrode adjacent to the electron transport layer is the first electrode.

13. The photovoltaic cell module according to claim 7, wherein the light harvesting layer comprises a bulk heterojunction layer comprising metal oxide nanoparticles and a hole conducting polymer which has been thermally treated to decrease its solubility, wherein the metal oxide is selected from the group consisting of: TiO₂, TiOₓ, ZnO, CeO₂ and Nb₂O₅.

14. The photovoltaic cell module according to claim 1, wherein the second electrode comprises silver.

15. The photovoltaic cell module according to claim 1, wherein the first electrode comprises ITO.

16. A method of making a photovoltaic cell module comprising a plurality of serially connected photovoltaic cells on a common substrate, comprising the steps of:
(a) forming a first electrode layer for each cell on the common substrate;
(b) printing a light-harvesting layer for each cell over the first electrode layer;
(c) printing a second electrode layer for each cell over the light-harvesting layer such that the second electrode layer of a first cell forms an electrical contact with the first electrode layer of an adjacent second cell without forming an electrical contact with the first electrode of the first cell or the light-harvesting layer of the second cell.

17-35. (canceled)

36. A photovoltaic cell module comprising a plurality of photovoltaic cells in the form of serially-connected nested loops each having a substantially identical light-harvesting area.

37. A photovoltaic cell module according to claim 36, wherein the cells are located on a common substrate.

38. A photovoltaic cell module according to claim 36, wherein the light harvesting layer comprises a conducting polymer.

39. A photovoltaic cell module according to claim 36, wherein the light harvesting layer comprises a mixture of a conducting polymer and metal oxide nanoparticles.

40. A photovoltaic cell module according to claim 39, wherein the metal oxide is selected from the group consisting of: TiO₂, TiOₓ, CeO₂, Nb₂O₅ and ZnO.

41. A photovoltaic cell module according to claim 40, wherein each cell further comprises an electron transport layer comprising metal oxide nanoparticles adjacent the first electrode and a hole conducting layer adjacent the second electrode.

42. A photovoltaic cell module according to claim 41, wherein each cell comprises:
(a) a first electrode layer;
(b) an electron transport layer which is a metal oxide nanoparticle layer, wherein the metal oxide is selected from the group consisting of: TiO₂, TiOₓ and ZnO;
(c) a bulk heterojunction layer comprising metal oxide nanoparticles and a hole conducting polymer which has been thermally treated to decrease its solubility, wherein the metal oxide is selected from the group consisting of: TiO₂, TiOₓ, ZnO, CeO₂ and Nb₂O₅;
(d) a hole transporting layer; and
(e) a second electrode layer.

43. The photovoltaic cell module according to claim 36, wherein the photovoltaic cell module is a solar cell module.

44. The photovoltaic cell module according to claim 36, wherein each of the photovoltaic cells is in the form of a closed loop.

45. The photovoltaic cell module according to claim 36, wherein each of the photovoltaic cells is in the form of an open loop.

46. An item comprising a photovoltaic device according to claim 1, a power consuming device and/or power storing means.

47. An item according to claim 46, wherein the power consuming device is a radio.

48. An item according to claim 46, wherein the power storing means is a rechargeable battery.

49. An item according to claim 46, which is a hat.

50. An item comprising a photovoltaic device according to claim 36, a power consuming device and/or power storing means.

51. An item according to claim 50, wherein the power consuming device is a radio.

52. An item according to claim 50, wherein the power storing means is a rechargeable battery.

53. An item according to claim 50, which is a hat.
